(19) United States
(12) Patent Application Publication
(10) Pub. No.: US 2017/0247810 A1
(43) Pub. Date: Aug. 31, 2017

(54) SYSTEM FOR MEASURING MATERIAL THICKNESSES AT HIGH TEMPERATURES

(71) Applicant: Varian Semiconductor Equipment Associates, Inc., Gloucester, MA (US)

(72) Inventors: Peter L. Kellerman, Essex, MA (US); Ala Moradian, Beverly, MA (US); Frank Sinclair, Boston, MA (US)

(21) Appl. No.: 15/511,783

(22) PCT Filed: Oct. 16, 2015
(86) PCT No.: PCT/US2015/055877

§ 371 Date: Mar. 16, 2017

Related U.S. Application Data
(60) Provisional application No. 62/065,276, filed on Oct. 17, 2014.

(51) Int. Cl. C30B 15/20; C30B 29/06; G01N 29/28; G01N 29/07; G01N 29/24; C30B 15/00; C30B 29/64

(52) U.S. Cl. CPC C30B 15/206; C30B 15/002; C30B 29/06; C30B 29/64; G01N 29/07; G01N 29/2462; G01N 29/28; G01N 2291/02854

(57) ABSTRACT

A sheet-forming apparatus including a crucible for holding a melt of material and a solid sheet of the material disposed within the melt, a crystallizer disposed above the crucible and configured to form the sheet from the melt, and an ultrasonic measurement system disposed adjacent the crystallizer, the ultrasonic measurement system comprising at least one ultrasonic measurement device including a waveguide coupled to an ultrasonic transducer for directing an ultrasonic pulse through the melt.

### FIELD OF THE DISCLOSURE

Embodiments of the present disclosure relate generally to systems for locating interfaces between different materials and, more particularly, to a system for locating interfaces between material layers in a high temperature environment.

### BACKGROUND OF THE DISCLOSURE

There are a number of processing and manufacturing applications wherein it is either advantageous or necessary to locate interfaces between various, disparate materials in harsh or extreme environments. For example, semiconductor substrates are sometimes produced using a technique wherein monocrystalline sheets are grown from a melt of a given material, such as silicon. This is accomplished by crystallizing a thin, solid layer of the given material at a given position on a surface of a melt composed of the given material, and pulling the thin, solid layer along a pull direction. As the monocrystalline material is drawn along the pull direction, a ribbon of monocrystalline material may form wherein one end of the ribbon remains stationary at the given position or crystallization region wherein crystallization takes place. This crystallization may necessitate an intense cooling device or “crystallizer.” This crystallization region may define a crystallization front (leading edge) between the monocrystalline sheet and the melt defined by a crystal facet formed at the leading edge.

In order to sustain the growth of this faceted leading edge in a steady-state condition with the growth speed matching the pull speed of the monocrystalline sheet, or “ribbon,” intense cooling may be applied by a crystallizer in the crystallization region. This may result in the formation of a monocrystalline sheet whose initial thickness is commensurate with the intensity of the cooling applied, the initial thickness often being on the order of 1-2 mm in the case of silicon ribbon growth. For applications such as forming solar cells from a monocrystalline sheet or ribbon, a target thickness may be on the order of 200 μm or less. This necessitates a reduction in thickness of the initially formed ribbon. This may be accomplished by heating the ribbon over a region of a crucible containing the melt as the ribbon is pulled in a pulling direction. As the ribbon is drawn through the region while the ribbon is in contact with the melt, a given thickness of the ribbon may melt back, thus reducing the ribbon thickness to a target thickness. This melt-back approach is particularly well suited in the so-called Floating Silicon Method (FSM), wherein a silicon sheet is formed on the surface of a silicon melt according to the procedures generally described above.

During growth of a monocrystalline sheet using a method such as FSM, sheet thickness may vary across the width of the monocrystalline sheet along a transverse direction perpendicular to the pull direction. This may vary from run to run, or even within a run, where a run corresponds to a process producing one ribbon of monocrystalline material. Additionally, because the final target thickness of a ribbon may be a factor of ten thinner than the initial thickness, precise control of thickness uniformity may be especially d. For example, a device application may specify a substrate thickness of 200 μm+/−20 μm. If a monocrystalline sheet is crystallized with an initial thickness of 2 mm near the crystallizer and an initial thickness variation of 2% (or 40 μm), with no correction of this initial thickness variation, after the ribbon is thinned to 200 μm thickness by drawing the ribbon through a melt-back region, the thickness variation of 40 μm now constitutes a 20% variation in thickness. This may render the ribbon useless for its intended application. Moreover, the thickness of a ribbon may vary along the transverse direction in a manner not easily corrected by melting back the ribbon using a conventional heater.

In view of the foregoing, it would be advantageous to provide a system for measuring the thickness of the monocrystalline sheet, such system being able to operate within the harsh (i.e., hot and electrically-noisy) FSM operating environment with no interference and with no contamination of the melt. It would further be advantageous to provide such a system for determining the locations of interfaces between disparate materials (e.g., interfaces between liquids and solids, interfaces between liquids and gases, interfaces between different solids, interfaces between different liquids, etc.) in virtually any type of crystal solidification application (e.g. Cz, DSS), as well as in glass and metallurgical applications, wherein material interfaces are otherwise difficult or impossible to locate.

### SUMMARY

This Summary is provided to introduce a selection of concepts in a simplified form further described below in the Detailed Description. This Summary is not intended to identify key features or essential features of the claimed subject matter, nor is it intended as an aid in determining the scope of the claimed subject matter.

An exemplary embodiment of a sheet-forming apparatus in accordance with an embodiment of the present disclosure may include a crucible for holding a melt of material and a solid sheet of the material disposed within the melt, a crystallizer disposed above the crucible and configured to form the sheet from the melt, and an ultrasonic measurement system disposed adjacent the crystallizer, the ultrasonic measurement system comprising at least one ultrasonic measurement device including a waveguide coupled to an ultrasonic transducer for directing an ultrasonic pulse through the melt.

An exemplary embodiment of a system for measuring a thickness of a sheet on a surface of a melt in accordance with the present disclosure may include at least one ultrasonic measurement device including a waveguide coupled to an ultrasonic transducer for directing an ultrasonic pulse through the melt and the sheet.

An exemplary method for determining locations of material interfaces in a sheet-forming apparatus in accordance with the present disclosure may include directing an ultrasonic pulse through a melt of material in the sheet-forming apparatus, and deriving, from reflections of the ultrasonic pulse at boundaries of the melt, the locations of the material interfaces.

### BRIEF DESCRIPTION OF THE DRAWINGS

By way of example, various embodiments of the disclosed device will now be described, with reference to the accompanying drawings, wherein:

FIG. 1 is a cross-sectional side view illustrating an ultrasonic measurement system in accordance with an embodiment of the present disclosure;

FIG. 2 is a cross-sectional side view illustrating an apparatus for separating a sheet from a melt in accordance with the present disclosure;

FIG. 3 is a cross-sectional front view taken along the plane A-A in FIG. 2 illustrating an ultrasonic measurement system of the apparatus shown in FIG. 2;

FIG. 4a is a cross-sectional front view illustrating a portion of the ultrasonic measurement system shown in FIG. 3;

FIG. 4b is a detail cross-sectional front view illustrating a waveguide of the ultrasonic measurement system shown in FIG. 4a; and

FIG. 5 includes a graph and a chart illustrating exemplary times and amplitudes of reflected ultrasonic pulses generated by the ultrasonic measurement system of the present disclosure.

FIG. 6 is a flow diagram illustrating an exemplary method in accordance with an embodiment of the present disclosure.

### DETAILED DESCRIPTION

A system for measuring the thickness of a sheet on the surface of a melt in accordance with the present disclosure will now be described more fully hereinafter with reference to the accompanying drawings, wherein certain embodiments of the system are shown. The system may be embodied in many different forms and are not to be construed as being limited to the embodiments set forth herein. These embodiments are provided so this disclosure will be thorough and complete, and will fully convey the scope of the system to those skilled in the art. In the drawings, like numbers refer to like elements throughout.

The embodiments of the system disclosed herein are described in connection with the production of solar cells. Additionally or alternatively, these embodiments also may be used to produce, for example, integrated circuits, flat panels, light-emitting diodes (LEDs), or other substrates known to those skilled in the art. Furthermore, while a silicon melt is described, the melt may contain germanium, silicon and germanium, gallium, gallium nitride, silicon carbide, sapphire, other semiconductor or insulator materials, or other materials known to those skilled in the art. Thus, the disclosure is not limited to the specific embodiments described below.

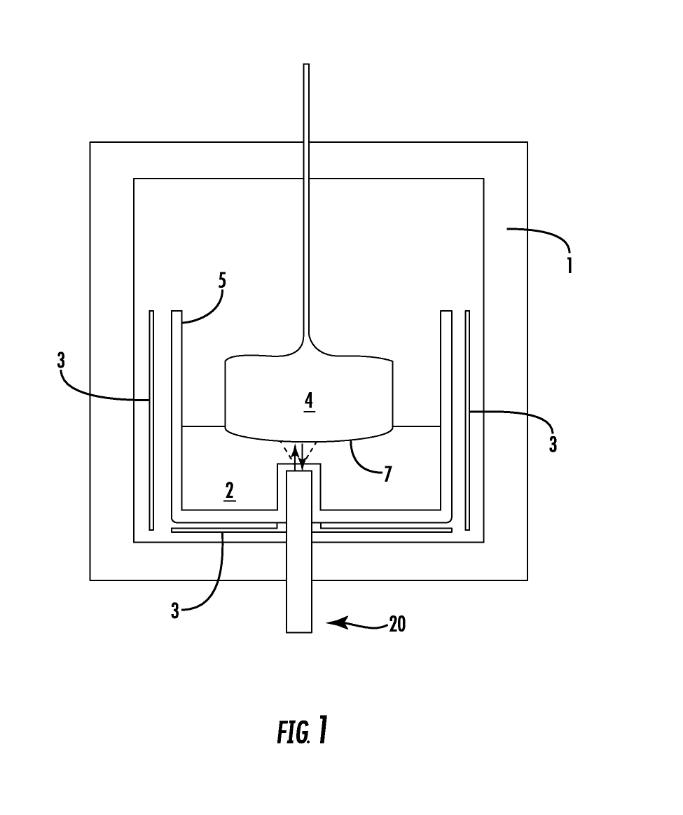

FIG. 1 is a cross-sectional side view of an ultrasonic measurement system 20 (hereinafter “the system 20”) configured to precisely locate interfaces between disparate materials, such as a liquid 2 and a solid 4 partially submerged in the liquid 2. In the example of FIG. 1, a furnace chamber 1 encloses heaters 3 used to heat a crucible 5 and a liquid 2 therein. In particular, the system 20 may be used to measure the position of an interface 7 formed between the liquid 2 and solid 4. More generally, the system 20 can be used to determine the locations of interfaces between disparate materials (e.g., interfaces between liquids and solids, interfaces between liquids and gases, interfaces between different solids, interfaces between different liquids, etc.) in virtually any type of crystal solidification application (e.g., Czochralski (Cz), DSS, Kyropolous (Ky)), as well as in glass and metallurgical applications.

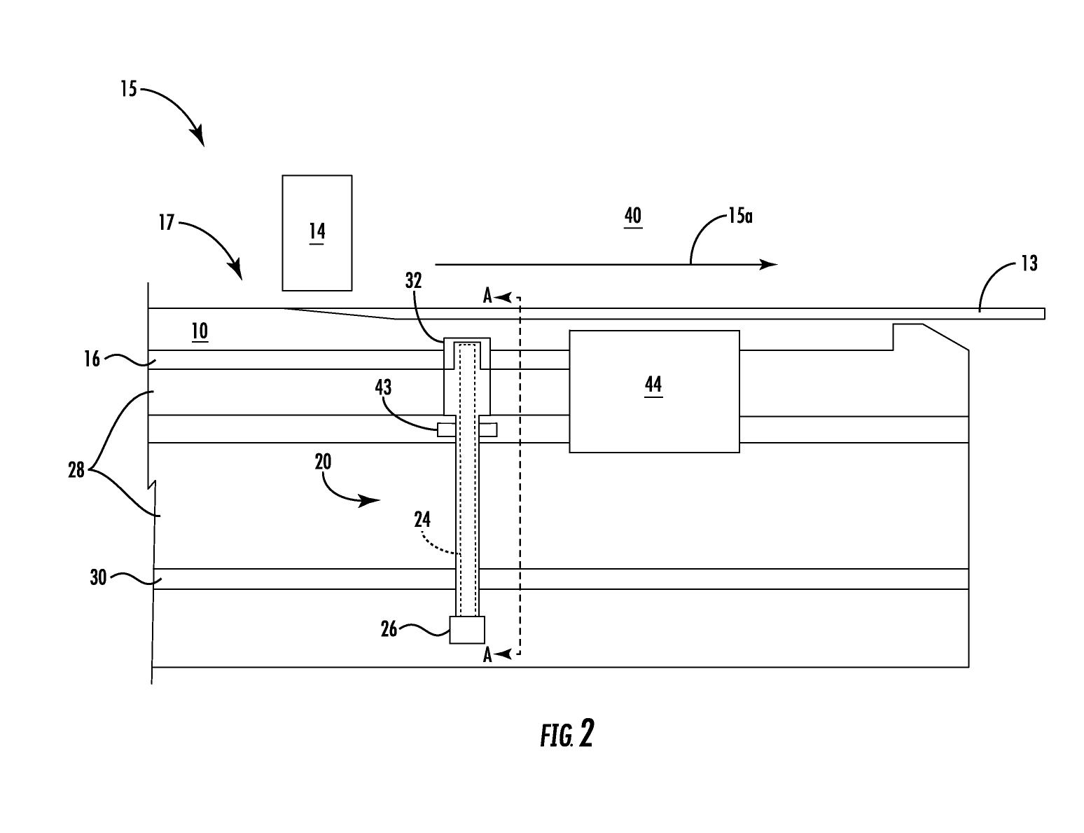

A non-limiting example of an application wherein the system 20 can be implemented is shown in FIG. 2, illustrating a cross-sectional side view of an embodiment of an apparatus 15 for forming a crystalline sheet from a melt 10. The sheet-forming apparatus 15 may include a vessel 16, such as a crucible, configured to contain the melt 10. The vessel 16 may be formed, for example, of tungsten, boron nitride, aluminum nitride, molybdenum, graphite, silicon carbide, or quartz. The melt 10 may be, for example, silicon. A sheet 13 may be formed on the melt 10. While the sheet 13 is illustrated in FIG. 2 as floating entirely within the melt 10, the sheet 13 may instead be partially submerged in the melt 10 or may float on top of the melt 10. In one instance, only 10% of the sheet 13 may protrude from above the top surface of the melt 10. The melt 10 may circulate within the sheet-forming apparatus 15.

In one particular embodiment, the vessel 16 may be maintained at a temperature slightly above 1412° C. For silicon, 1412° C. represents the freezing temperature or “interface temperature.” By maintaining the temperature of the vessel 16 slightly above the freezing temperature of the melt 10, a crystallizer 14 positioned above the melt 10 may rapidly cool the melt 10 to obtain a desired freezing rate of the sheet 13 on or in the melt 10 as the melt 10 passes below the crystallizer 14.

Measuring the thickness of the sheet 13 has many advantages. Such measurement may be used to facilitate a feedback mechanism or process control system for production of the sheet 13. This may ensure a desired thickness of the sheet 13 is acquired. In-situ measurement may allow real-time monitoring of the thickness of the sheet 13 as it is formed on the melt 10. This may reduce waste of the melt 10 and enable a continuous sheet 13 to be formed.

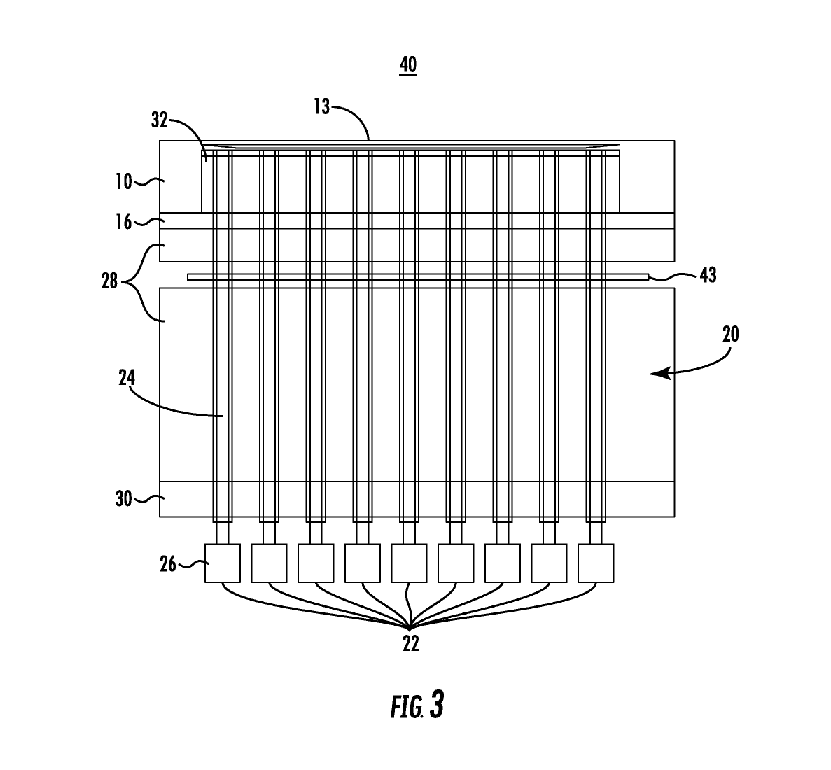

In one non-limiting embodiment, the apparatus 15 may include the ultrasonic sheet measurement system 20 for measuring the thickness of the sheet 13 as shown in FIGS. 2 and 3. The system 20 may include an array of ultrasonic measurement devices 22 (hereinafter “the measurement devices 22”), disposed in a laterally-spaced arrangement below a surface of the melt 10 as best illustrated in the front view of the system 20 shown in FIG. 3. Each of the measurement devices 22 may include an elongated waveguide 24 coupled to, and extending upwardly from, a respective ultrasonic transducer 26. The transducers 26 may be separated from the bottom of the vessel 16 by one or more layers of thermally-insulating material 28 as well as a layer of water cooled metal 30 (e.g., aluminum) for protecting the transducers 26 from heat.

The upper ends of the waveguides 24 may be disposed within a protective enclosure 32 extending upwardly through (or from) a floor of the vessel 16. The protective enclosure 32 may be formed of, for example, tungsten, boron nitride, aluminum nitride, molybdenum, graphite, silicon carbide, or quartz, and may allow the uppermost tips of the waveguides 24 to extend to a position slightly below (e.g., <5 mm) the sheet 13 while preventing contact between the waveguides 24 and the melt 10. The protective enclosure 32 thus protects the melt 10 from contamination by the waveguides 24, yet allows the resolution of the waveguide measurement to be nearly equal to the diameter of the waveguide 24 (e.g., ˜1 cm) as further described below.

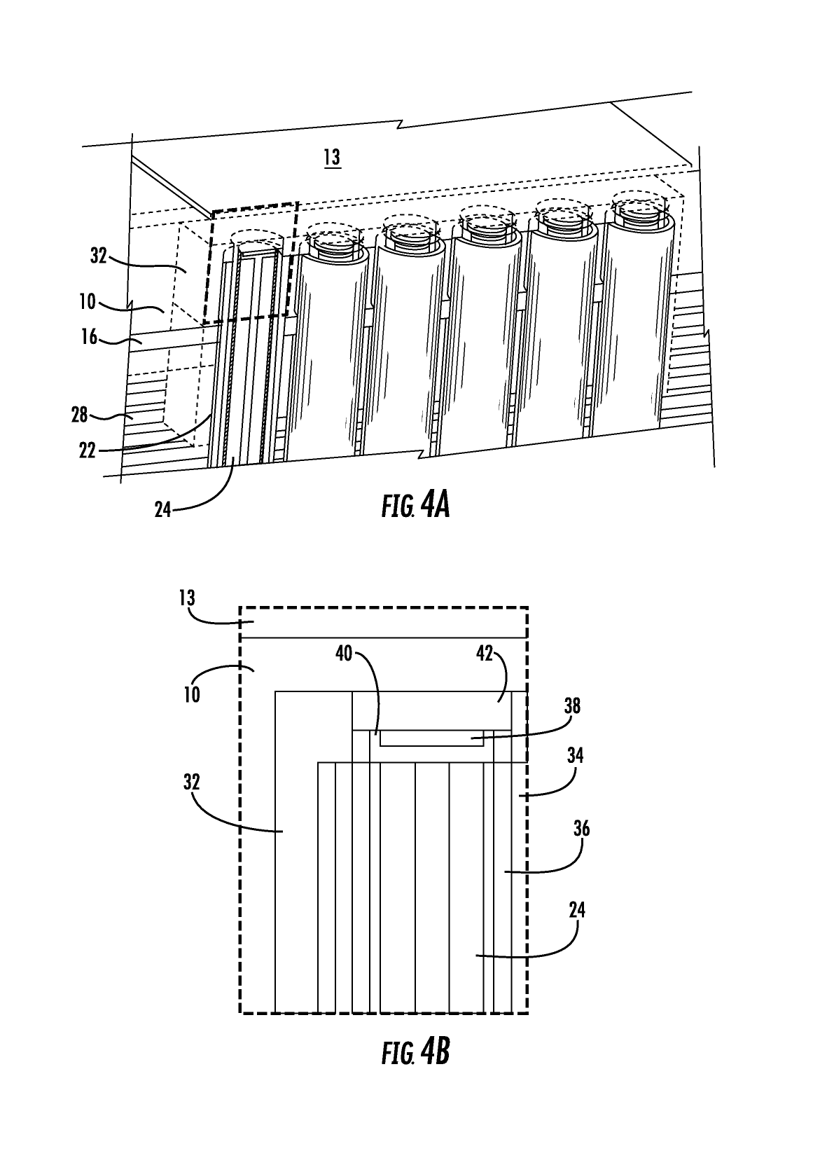

Referring to the detailed views of the measurement devices 22 shown in FIGS. 4a and 4b, each of the waveguides 24 may be configured to transmit an ultrasonic wave pulse from a respective transducer 26 (shown in FIGS. 2 and 3) to the high temperature environment of the melt 10 while mitigating distortion of a wave pulse and while mitigating “trailing pulses” caused by reflections between the walls of a waveguide 24. For example, each waveguide 24 may be formed from a coiled sheet of high-temperature metal, such as high-carbon steel or tungsten. By dimensioning the sheet with the sheet thickness being less than the ultrasound pulse wavelength, and with the coil length greater than the ultrasound pulse wavelength, a “mono-mode” condition can be reached where the ultrasonic transmission is virtually dispersion free. In another non-limiting example, each waveguide 24 may be a solid cylinder having tapered walls, such cylinder being formed of a high-temperature, low-thermal conductivity material, such as ceramic. The surface of such a ceramic cylinder may be textured to reduce trailing echoes.

Referring to FIG. 4b, each waveguide 24 may be surrounded by an insulating sleeve 34 made of an alumina-silica composite (sold under the brand name ZIRCAR) or similar material. An inner diameter of the insulating sleeve 34 may be larger than the outer diameter of the waveguide 24. The insulating sleeve 34 may thus define an annular, air or argon gas-filled gap 36 around the waveguide 24. Additionally, a “puck” 38 of molten metal (e.g., silver, copper, aluminum, etc.) may be disposed within a tip 40 of each waveguide 24, such as within a cup-like recess, vertically intermediate the waveguide 24 and the ceiling 42 of the protective enclosure 32. The puck 38 may function as a low acoustic impedance coupling for minimizing acoustic loses.

During operation of the system 20, ultrasonic pulses are generated by the transducers 26 and are channeled by the waveguides 24 upwardly through the protective enclosure 32, the melt 10, the sheet 13, and a gaseous (e.g., argon gas) atmosphere 40 above the melt 10. The ultrasonic pulses are partially reflected at each material interface, and such reflections are detected by the transducers 26. The relative strength R of each reflection is determined by the difference in acoustic impedances z of materials across each material interface, as given by the equation:

$$R = {( \frac{{Z}_{i + 1} - {Z}_{i}}{{Z}_{i + 1} + {Z}_{i}} )}^{2}$$

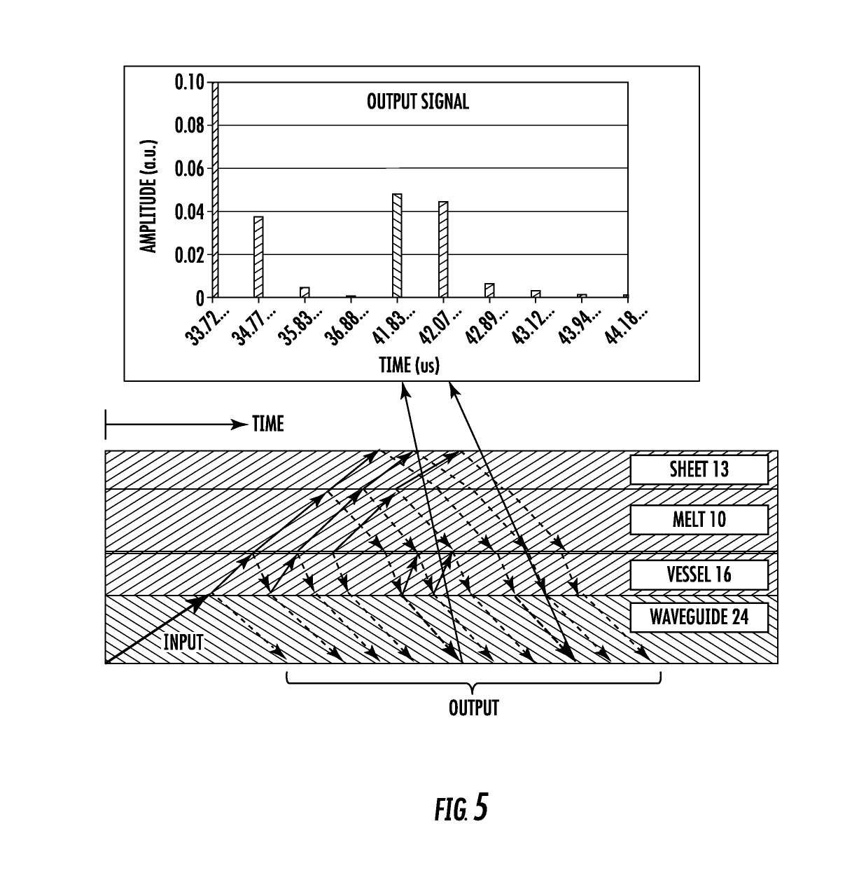

Based on the acoustic properties of the waveguides 24, the protective enclosure 32, the melt 10, the sheet 13, and the gaseous atmosphere 40, as well as the velocity of sound and the thickness of each of the material layers, a “time of flight” can be calculated for each of the partial reflections detected by the transducers 26 as illustrated in FIG. 5. Accounting for all of the reflections, including the timing and attenuation of the reflections, a correspondence between each reflection and each material interface may be determined. The reflections from the top and bottom surfaces of the sheet 13 are easily distinguishable in amplitude, with a time difference of approximately 0.2 μs therebetween. A conventional unfocused piezoelectric transducer (pulser-receiver) operating at 20 MHz would be able to generate ultrasonic pulses with periods of approximately 0.05 μs. This would provide adequate resolution for detecting the 0.2 μs separation between the signals representing the thickness measurement of the sheet 13.

Thus, each of the ultrasonic measurement devices 22 may be used to measure the thickness of a respective lateral cross-section of the sheet 13, wherein the width of each respective lateral cross-section is approximately equal to the diameter of a waveguide 24. The lateral array of ultrasonic measurement devices 22 in the system 20 may therefore collectively yield a “thickness profile” of the sheet 13 across the width of the entire sheet 13. Since the diameter of each waveguide 24 is approximately 1 cm, one can obtain a thickness profile resolution of approximately 1 cm, provided the waveguides 24 are positioned within a few millimeters of the sheet 13 being measured.

The above-described pulse-echo technique is time-based (as opposed to signal strength-based), and is therefore independent of variations in transducer and material properties. This allows the system 20 to measure the thickness profile of the sheet 13 with no cross-calibration of the individual ultrasonic measurement devices 22.

In order to avoid thermal disturbance to the melt 10 and/or the sheet 13, the system 20 may be provided with one or more compensation heaters 43 disposed adjacent the waveguides 24 below the vessel 16 as shown in FIGS. 2 and 3. The compensation heater 43 may heat the waveguides 24 sufficiently to prevent heat from the melt 10 from flowing into waveguides 24 and creating cold regions in the melt 10, possibly creating defects in the sheet 13. For example, assuming the each waveguide 24 has an effective thermal conductivity of approximately 200 W/mK (in the case of coiled steel) and each waveguide 24 is approximately 1 cm in diameter and approximately 15 cm long, it would take approximately 15 W of power to maintain the compensation heater 43 at the melt temperature of 1412 C for heating the waveguides 24. With the waveguides 24 heated thusly, there would be little or no temperature gradient in the waveguides 24 adjacent the melt 10, and thus little or no heat would flow from the melt 10 into the waveguides 24.

The thickness profile of the sheet 13, as well as other thickness measurements yielded by the system 20 of the present disclosure, can be used for a variety of purposes. For example, when the sheet 13 is initially created in the melt 10, the sheet 13 is formed with a leading edge facet resulting in the sheet thickness being initialized at a thickness commensurate with the length of the crystallizer 14 (shown in FIG. 2), where the sheet thickness may commonly be greater than 1 mm. For solar cells, the optimal sheet thickness is <200 μs (substrates are often approximately 180 μs thick). Thus, there is a need to melt-back portions of the initialized sheet 13 to a desired thickness. For optimal production efficiency, this melt-back can be performed while the sheet 13 is still in contact with the melt 10 in the crystal growth furnace.

A segmented melt-back heater (SMBH) 44 may be disposed below/within the melt 10 as shown in FIG. 2 and may facilitate selective melt-back and thinning of desired portions of the sheet 13. Thus, the uniformity of the sheet thickness profile may be “tuned.” The SMBH 44 may include a plurality of laterally-spaced heaters, wherein the output of each heater is individually controllable for collectively yielding a controllable lateral heat profile. The initial sheet thickness profile measured by the system 20 may be communicated to a controller (not shown), and the controller may in-turn tune the heat profile of the SMBH 44 to selectively melt-back the sheet 13 to obtain a desired final sheet thickness and uniformity. In one example, the final sheet profile may be uniform to within approximately 10 μm (for solar cells) and the initial sheet thickness profile can be measured to an accuracy of approximately 10 μm.

In one example, it may be advantageous to measure the sheet thickness profile of the sheet directly upstream of the SMBH 44 so any fluctuations in the sheet thickness profile can be corrected by the SMBH 44 with minimal or no lag. The system 20 may therefore be positioned directly upstream of the SMBH 44 as shown in FIG. 2. The system 20 may alternatively be positioned downstream of the SMBH 44.

The system 20 may additionally or alternatively be used to measure the thickness of materials in the apparatus 15 other than the sheet 13. For example, the system 20 may be used to measure the thickness (depth) of the melt 13 in order to determine whether, and to what degree, the melt 10 is to be replenished. The system 20 may be used to determine the precise locations of interfaces between materials in the apparatus 15. For example, the system 20 may be used to determine the location of the interface between the melt 10 and the sheet 13 even if such interface is located below the surface of the melt 10 (i.e., if the sheet 13 is submerged in the melt 10). More generally, the system 20 may be used to determine the locations of solidification interfaces (i.e., interfaces between liquids and solids) in virtually any crystal solidification application (e.g. Cz, DSS), as well as glass and metallurgical applications, wherein solidification interfaces are otherwise difficult or impossible to locate.

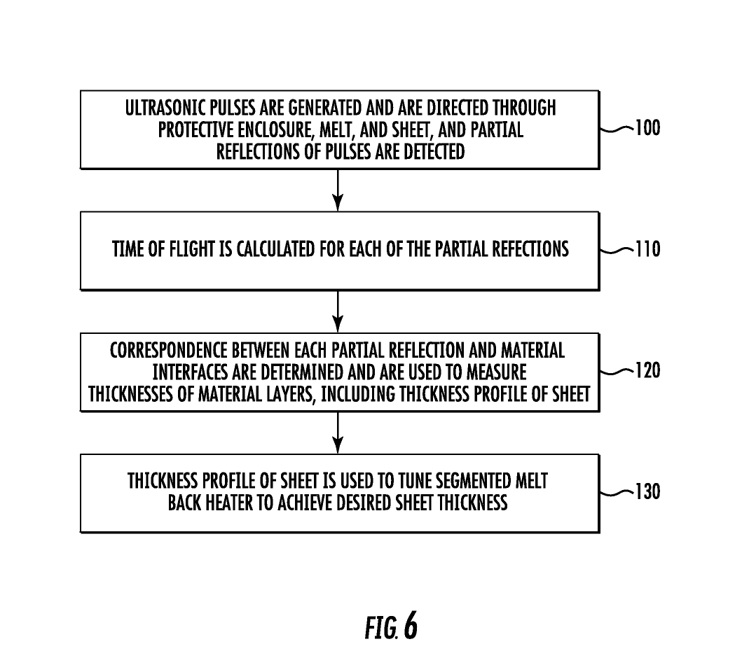

Referring to FIG. 6, a flow diagram illustrating an exemplary method for locating interfaces between material layers in a high temperature environment in accordance with the present disclosure is shown. Such method will now be described in conjunction with the schematic representations of the apparatus 15 and system 20 shown in FIGS. 2 and 3.

In box 100 of the exemplary method, ultrasonic pulses are generated by the transducers 26 and are channeled by the waveguides 24 upwardly through the protective enclosure 32, the melt 10, the sheet 13, and a gaseous (e.g., argon gas) atmosphere 40 above the melt 10, whereafter the ultrasonic pulses are partially reflected at each material interface, and such reflections are detected by the transducers 26.

In box 110 of the exemplary method, a “time of flight” can be calculated for each of the partial reflections detected by the transducers 26 based on the acoustic properties of the waveguides 24, the protective enclosure 32, the melt 10, the sheet 13, and the gaseous atmosphere 40, as well as the velocity of sound and the thickness of each of the material layers.

In box 120 of the method, accounting for all of the partial reflections detected by the transducers 26, including the timing and attenuation of the reflections, a correspondence between each reflection and each material interface may be determined. This correspondence may be used to measure the thickness of a respective lateral cross-section of the sheet 13, wherein the width of each respective lateral cross-section is approximately equal to the diameter of a waveguide 24. The lateral array of ultrasonic measurement devices 22 in the system 20 may therefore collectively yield a “thickness profile” of the sheet 13 across the width of the entire sheet 13.

In box 130 of the exemplary method, the thickness profile of the sheet 13 may be used to tune a heat profile of the segmented melt-back heater (SMBH) 44 in order to melt back selected portions of the sheet 13 to achieve a sheet having a desired thickness.

Thus, the above-described system 20 may provide numerous advantages relative to conventional measurement systems employed in sheet forming apparatuses. For example, the system 20 is specially adapted to measure the thickness of a monocrystalline sheet within a harsh (i.e., hot and electrically-noisy) FSM operating environment with no interference and with no contamination of a melt. Additionally, the system 20 is capable of determining the locations of interfaces between disparate materials (e.g., interfaces between liquids and solids, interfaces between liquids and gases, interfaces between different solids, interfaces between different liquids, etc.) in virtually any type of crystal solidification application (e.g. Cz, DSS), as well as in glass and metallurgical applications, wherein material interfaces are otherwise difficult or impossible to locate.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize its usefulness is not limited thereto and the present disclosure may be beneficially implemented in any number of environments for any number of purposes. Accordingly, the claims set forth below are to be construed in view of the full breadth and spirit of the present disclosure as described herein.

1. A sheet-forming apparatus comprising:
a crucible for holding a melt of material and a solid sheet of the material disposed within the melt;
a crystallizer disposed above the crucible and configured to form the sheet from the melt; and
an ultrasonic measurement system disposed adjacent the crystallizer, the ultrasonic measurement system comprising at least one ultrasonic measurement device including a waveguide coupled to an ultrasonic transducer for directing an ultrasonic pulse through the melt.

2. The sheet-forming apparatus of claim 1, wherein the waveguide is further configured to direct the ultrasonic pulse through the sheet.

3. The sheet-forming apparatus of claim 1, wherein the ultrasonic measurement device comprises a plurality of ultrasonic measurement devices disposed in a laterally-spaced arrangement across a width of the melt.

4. The sheet-forming apparatus of claim 1, wherein a tip of the waveguide is disposed within a protective enclosure within the melt.

5. The sheet-forming apparatus of claim 4, further comprising a quantity of molten metal disposed intermediate the tip of the waveguide and the protective enclosure for providing a low acoustic impedance coupling therebetween.

6. The sheet-forming apparatus of claim 4, further comprising a segmented melt-back heater in communication with the ultrasonic measurement system and configured to melt back portions of the sheet based on a thickness of the sheet measured by the ultrasonic measurement system.

7.-15. (canceled)

16. The sheet-forming apparatus of claim 1, wherein the waveguide is further configured to direct the ultrasonic pulse through the sheet, a tip of the waveguide is disposed within a protective enclosure within the melt, a quantity of molten metal is disposed intermediate the tip of the waveguide and the protective enclosure for providing a low acoustic impedance coupling therebetween, and a segmented melt-back heater is communicatively coupled to the ultrasonic measurement system and is configured to melt back portions of the sheet based on a thickness of the sheet measured by the ultrasonic measurement system

17. A system for measuring a thickness of a sheet of material on a surface of a melt of the material, the system comprising at least one ultrasonic measurement device including a waveguide coupled to an ultrasonic transducer for directing an ultrasonic pulse through the melt and the sheet.

18. The system of claim 17, wherein the at least one ultrasonic measurement device comprises a plurality of ultrasonic measurement devices disposed in a laterally-spaced arrangement across a width of the melt.

19. The system of claim 17, wherein a tip of the waveguide is disposed within a protective enclosure within the melt and below the sheet.

20. A method for determining locations of material interfaces in a sheet-forming apparatus comprising:
directing an ultrasonic pulse through a melt of material in the sheet-forming apparatus; and
deriving, from reflections of the ultrasonic pulse at boundaries of the melt, the locations of the material interfaces.

21. The method of claim 20, further comprising:
directing the ultrasonic pulse through a sheet of the material disposed in the melt; and
deriving, from reflections of the ultrasonic pulse at boundaries of the sheet, a thickness of the sheet.

22. The method of claim 21, further comprising calculating a time of flight for the reflections at the boundaries of the sheet in order to derive the thickness of the sheet.

23. The method of claim 12, wherein directing the ultrasonic pulse through the sheet of material comprises directing a plurality of ultrasonic pulses through the sheet of material to ascertain a thickness profile of the sheet across a width of the sheet.

24. The method of claim 23, further comprising using the ascertained thickness profile of the sheet to tune a heat profile of a segmented melt-back heater in order to melt back selected portions of the sheet.
